(19) United States
(12) Patent Application Publication
(10) Pub. No.: US 2010/0163286 A1
(43) Pub. Date: Jul. 1, 2010

(54) Circuit Board Structure and Manufacturing Method Thereof and Liquid Crystal Display Containing the Same

(75) Inventor: Chien-Cheng Chang, Hsin-Chu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORPORATION, Hsin-Chu (TW)

(21) Appl. No.: 12/500,794

(22) Filed: Jul. 10, 2009

(30) Foreign Application Priority Data
Dec. 29, 2008 (TW) 97151281

(51) Int. Cl. H05K 1/09; H05K 1/00; H05K 3/02

(52) U.S. Cl. 174/257; 174/250; 29/846

(57) ABSTRACT

A circuit board structure and a manufacturing method thereof and a liquid crystal display (LCD) containing the same are disclosed. The circuit board structure comprises a flexible printed circuit board (FPC) and a printed circuit board. On a first surface of the printed circuit board opposite to a connection area (such as a gold fingers area) thereof for connecting to the FPC, dummy circuits are formed for maintaining uniform stress when the printed circuit board and the FPC are press-bonded. In the manufacturing method, an electrically-conductive layer is first formed on the first surface of the printed circuit board, and then first grooves and second grooves are formed on the electrically-conductive layer simultaneously, thereby forming real circuits and dummy circuits, wherein the depths of the first grooves and the second grooves are about the same, and the thicknesses of the dummy circuits and the real circuits are about the same.

### RELATED APPLICATIONS

This application claims priority to Taiwan Application Serial Number 97151281, filed Dec. 29, 2008, which is herein incorporated by reference.

### BACKGROUND

1. Field of Invention

The present invention relates to a circuit board structure and a manufacturing method thereof and a liquid crystal display (LCD). More particularly, the present invention relates to a circuit board structure having dummy circuits; a manufacturing method of the circuit board structure; and a LCD containing the circuit board structure.

2. Description of Related Art

With the advances of optical and semiconductor technologies, liquid crystal displays (LCDs) have been widely applied on the display apparatuses of electronic products. The existing liquid crystal display products, especially hand-held products, have been developed towards the design structures of lightness, thinness, shortness and smallness, and thus new materials and assembling skills are constantly presented to the market, wherein a chip on film (COF) is quite an important one thereof. The so-called COF is to directly mount a chip on a flexible printed circuit board (FPC). Such a connection method of COF results in higher integrity, and also allows the peripheral elements to be mounted together with the chip on the FPC.

In a conventional liquid crystal module (LCM) process, a backlight module, a display panel and a polarizer have to be assembled together, and one end of the COF is electrically connected to the display panel, and then the other end of the COF is press-bonded with a gold-fingers end of a printed circuit board. While a press-bonding step is performed in a board manufacturing plant to make a printed circuit board, stress concentration occurs on an area of the printed circuit board with no circuits printed on it, and there exists a lo thickness difference between the area of the printed circuit board with circuits and that of the printed circuit board without circuits. In addition, when a step for press-bonding the COF with the printed circuit board in a LCM plant, the problem of stress concentration occurring on the area of the printed circuit board with no circuits results in the failure in press-bonding the COF with the printed circuit board, and thus the COF and the printed circuit board cannot be electrically conducted to each other. In general, the average defect rate of the aforementioned press-bonding step is about 1-2%.

### SUMMARY

Hence, an aspect of the present invention is to provide a circuit board structure and a manufacturing method thereof and a LCD for improving the thickness uniformity of a printed circuit board, thereby overcoming the problem of failure in press-bonding a COF with the printed circuit board.

In accordance with an embodiment of the present invention, the circuit board structure comprises a printed circuit board, a plurality of real circuits and a plurality of dummy circuits. The real circuits are formed on a first area of one surface of the printed circuit board, wherein a first groove is formed between every two adjacent real circuits. The dummy circuits formed on a second area adjacent to the first area on the aforementioned surface of the printed circuit board, wherein a second groove is formed between every two adjacent dummy circuits, and the first groove and the second groove have substantially the same depths, and the dummy circuits and the real circuits have substantially the same thicknesses.

In accordance with another embodiment of the present invention, the lo circuit board structure further comprises a plurality of gold fingers. The gold fingers are formed on the other surface opposite to the aforementioned surface, and are substantially aligned with the first area and the second area of the printed circuit board. The real circuits are electrically connected to the gold fingers, and the dummy circuits are electrically insulated from the gold fingers.

In accordance with another embodiment of the present invention, the circuit board structure further comprises a flexible printed circuit board (FPC), such as a COF. One end of the FPC is press-bonded with the gold fingers.

In accordance with another embodiment of the present invention, the LCD incorporates the circuit board structure described above.

According to an embodiment of the present invention, in the manufacturing method of the circuit board structure, a base board is first provided. Then, an electrically-conductive layer is formed on one surface of the base board. Thereafter, a first area and a second area adjacent to the first area are defined on the electrically-conductive layer. Then, a plurality of first grooves and a plurality of second grooves are simultaneously formed on the first area and the second area, thereby respectively forming a plurality of real circuits on the first area, and a plurality of dummy circuits on the second area, wherein the first grooves and the second grooves have substantially the same depths, and the dummy circuits and the real circuits have substantially the same thicknesses.

According to another embodiment of the present invention, the manufacturing method of the circuit board structure further comprises the step of forming a plurality of gold fingers on the other surface opposite to the aforementioned surface of the base board, wherein the gold fingers are lo substantially aligned with the first area and the second area on the aforementioned surface of the base board, and the aforementioned real circuits are electrically connected to the gold fingers, and the aforementioned dummy circuits are electrically insulated from the gold fingers.

According to another embodiment of the present invention, the manufacturing method of the circuit board structure further comprises the step of providing a flexible printed circuit board (FPC), and the step of press-bonding one end of the FPC with the gold fingers.

With the application of the aforementioned circuit board structure and the manufacturing method thereof, the thickness uniformity of the printed circuit board can be improved, thus avoiding the problem of failure in press-bonding the FPC (COF) with the printed circuit board caused by stress concentration.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a schematic explosive view showing a circuit board structure of an embodiment of the present invention;

FIG. 2A is a schematic top view showing a printed circuit board of the embodiment of the present invention;

FIG. 2B is a schematic bottom view showing the printed circuit board of the embodiment of the present invention;

FIG. 2C is a schematic cross-sectional diagram viewed along line A-A′ in FIG. 2B;

FIG. 3 is a schematic bottom view showing a printed circuit board of another embodiment of the present invention;

FIG. 4 is a schematic structural diagram showing a LCD of an embodiment of the present invention; and

FIG. 5 is a schematic flow chart illustrating a manufacturing method of a circuit board structure according to an embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention is mainly to form “dummy circuits” on a backside of a printed circuit board's connection area, so that the stress generated by press-bonding the printed circuit board with a FPC can be uniform, thus avoiding the problem of press-bonding failure. The FPC applied in the present invention can be a COF, for example, and a connection area of the printed circuit board corresponding to the FPC can be gold fingers, for example. However, other types of FPC and connection areas of printed circuit board are also applicable to the present invention, and thus the present invention is not limited thereto.

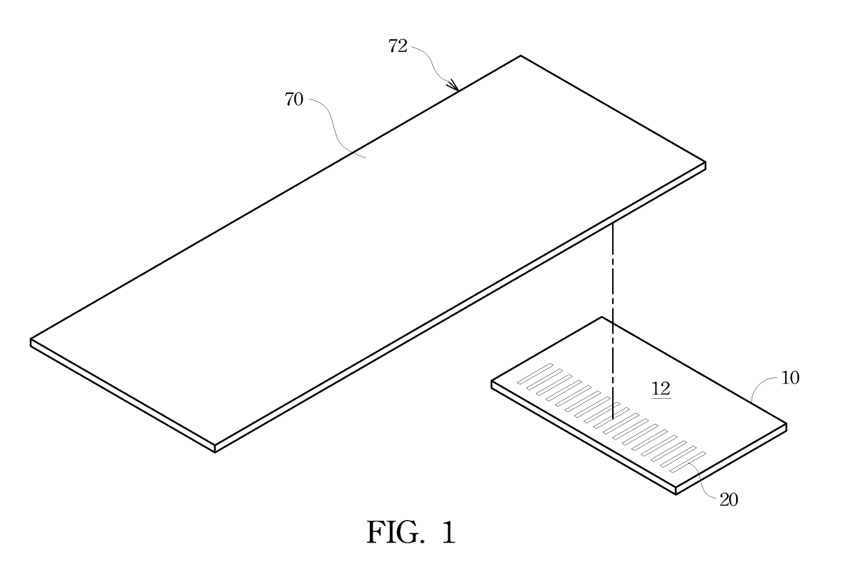

Referring to FIG. 1, FIG. 1 is a schematic explosive view showing a circuit board structure of an embodiment of the present invention. The circuit board structure of this embodiment comprises a FPC 70 and a printed circuit board 10. There are a plurality of gold fingers 20 disposed on a first surface 12 of the printed circuit board 10, and one end 72 of the FPC 70 is press-bonded with the gold fingers 20. Hereinafter, the printed circuit board 10 of this embodiment will be described.

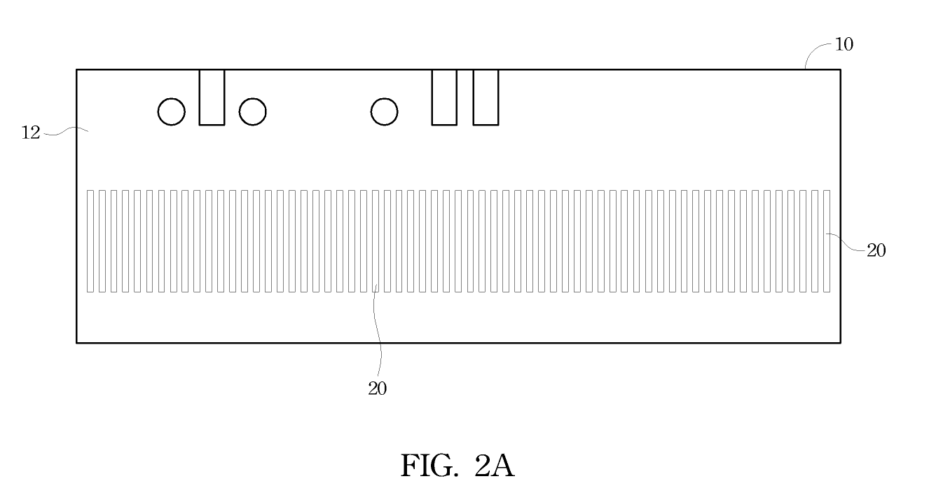

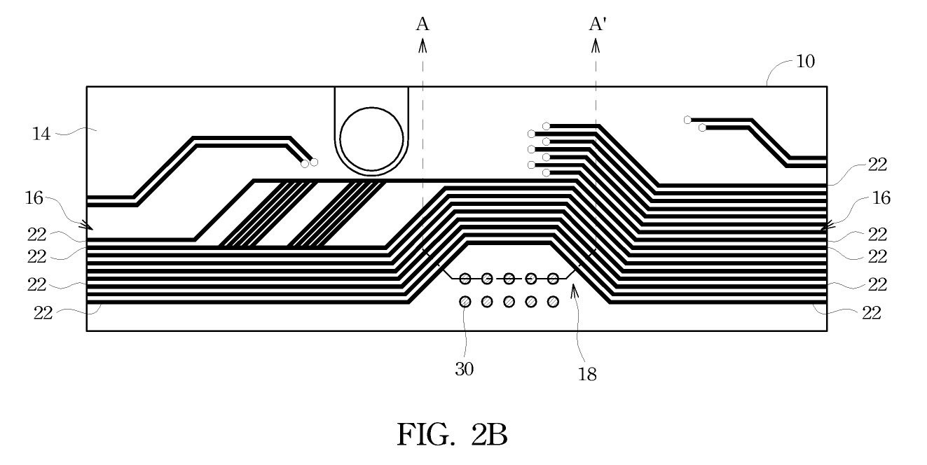

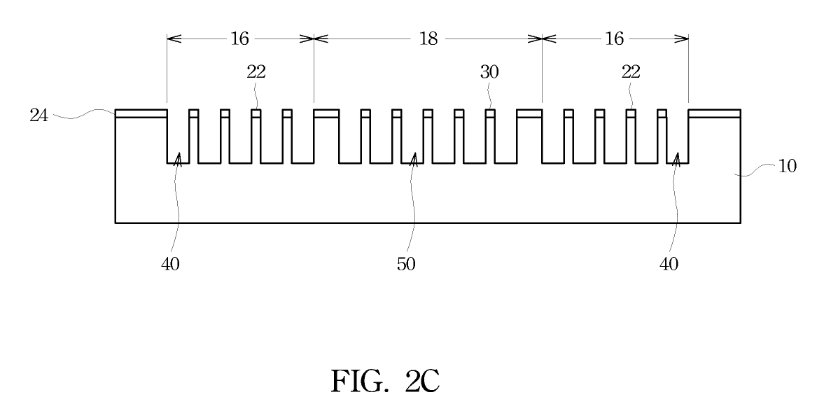

Referring to FIG. 2A, FIG. 2B and FIG. 2C, FIG. 2A, FIG. 2B and FIG. 2C are respective schematic top, bottom and cross-sectional views showing the printed circuit board 10 of the embodiment of the present invention, wherein FIG. 2C is viewed along line A-A′ in FIG. 2B. The printed circuit board 10 of this embodiment has a first surface 12 and a second surface 14 opposite to the first surface 12. The second surface 14 of the printed circuit board 10 has a first area 16 and a second area 18 adjacent to the first area 16, wherein there are a plurality of real circuits 22 formed on the first area 16, and there are a plurality of dummy circuits 30 formed on the second area 18. There are a plurality of gold fingers 20 formed on the first surface 12 of the printed circuit board 10, wherein the gold fingers 20 are substantially aligned with the first area 16 and the second area 18 located on the second surface 14 of the printed circuit board 10, and the real circuits 22 on the first area 16 are electrically connected to the gold fingers 20, and the dummy circuits 30 on the second area 18 are electrically insulated from the gold fingers 20. A first groove 40 is formed between every two adjacent real circuits 22, and a second groove 50 is formed between every two adjacent dummy circuits 30, as shown in FIG. 2C, wherein the depth of the first groove 40 is about the same as that of the second groove 50, and the thicknesses of the dummy circuits 30 and the real circuits 22 are about the same. With the arrangement of the second groove 50 and the dummy circuits 30, the thickness of the first area 16 can be made close to that of the second area 18, thus effectively improving the thickness uniformity of the printed circuit board 10. Since the first area 16 and the second area 18 of the printed circuit board 10 have excellent thickness uniformity, the problem of stress concentration occurring at the second area 18 on which no real circuits exist can be effectively avoided when the gold fingers 20 (the first area 16 and the second area 18) of the printed circuit board 10 are press-bonded with the FPC 70 (as shown in FIG. 1), thus greatly improving the average defect rate of the press-bonding step.

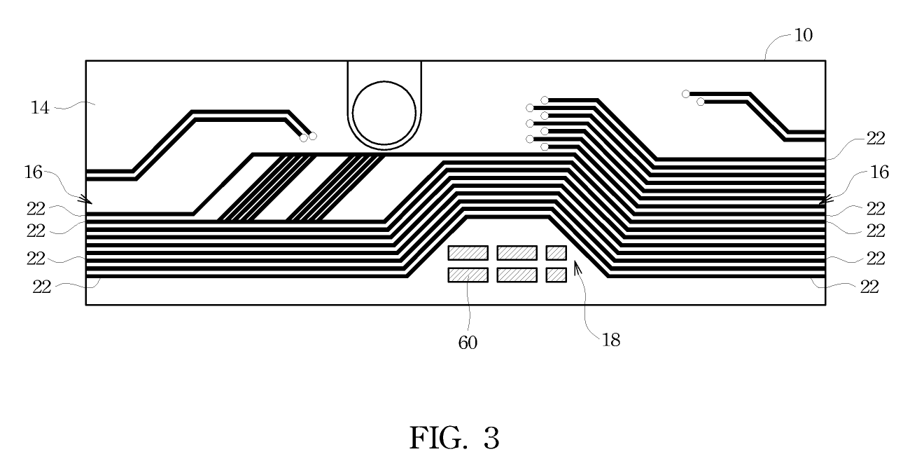

Such as shown in FIG. 2B, the shape of each dummy circuit 30 can be such as a circle, wherein the diameter of the circle is preferably ranged from about 100 μm to about 200 μm. Referring to FIG. 3, FIG. 3 is a schematic bottom view showing a printed circuit board of another embodiment of the present invention, wherein the shape of each dummy circuit 30 can be such as a rectangle, wherein the width of the rectangle is preferably ranged from about 100 μm to about 200 μm, and the length of the rectangle is preferably ranged from about 200 μm to about 500 μm. Further, the dummy circuits 30 are preferably spaced from the real circuits 22 at a distance that is greater than about 200 μm, thereby avoiding mutual interference. The ratio of the total area of the dummy circuits 30 to the area of the second area 18 is ranged from about 30% to about 90%, thereby effectively improving the thickness uniformity of the printed circuit board.

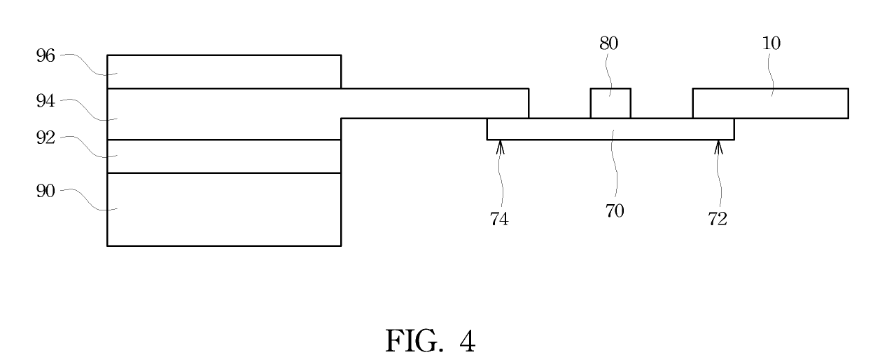

Referring to FIG. 4, FIG. 4 is a schematic structural diagram showing a lo LCD of an embodiment of the present invention. The LCD of this embodiment comprises a backlight module 90, a lower polarizer 92, a display panel 94, a FPC 70, a driving integrated circuit (IC) 80, a printed circuit board 10 and an upper polarizer 96. One end 74 of the FPC 70 is connected to the display panel 94, and the other end 72 of the FPC 70 is press-bonded with the printed circuit board 10. The printed circuit board 10 of this embodiment has the aforementioned dummy circuits and the real circuits thereon.

The manufacturing method of the circuit board structure of the present invention is explained in the below.

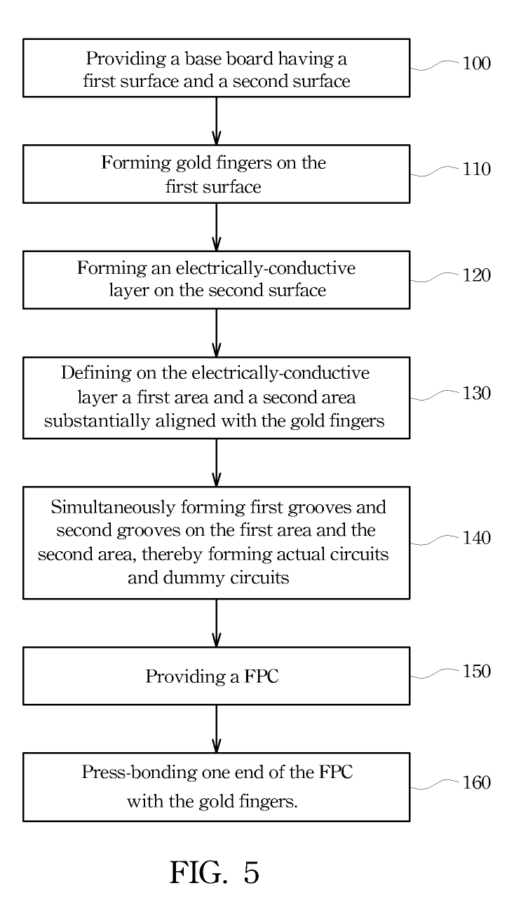

Referring to FIG. 2A, FIG. 2C and FIG. 5, FIG. 5 is a schematic flow chart illustrating a manufacturing method of a circuit board structure according to an embodiment of the present invention. In the manufacturing method of the circuit board structure of this embodiment, at first, step 100 is performed to provide a base board (printed circuit board 10) having a first surface 12 and a second surface 14, wherein the first surface 12 is opposite to the second surface 14. Thereafter, step 110 is performed to form a plurality of gold fingers 20 on the first surface 12. Then, step 120 is performed to form an electrically-conductive layer 24 on the second surface 14. Thereafter, step 130 is performed to define a first area 16 and a second area 18 on the electrically-conductive layer 24, wherein the first area 16 and the second area 18 are substantially aligned with the gold fingers 20. Then, by using a step of such as etching, step 140 is performed to simultaneously form a plurality of first grooves 40 and a plurality of second grooves 50 on the first area 16 and the second area 18, thereby respectively forming a plurality of real circuits 22 on the first area 16, and a plurality of dummy circuits 30 on the second area 18, lo wherein the depths of the first grooves 40 are about the same as the depths of the second grooves 50, and the thicknesses of the dummy circuits 30 are about the same as the thicknesses of the real circuits 22.

Referring to FIG. 1 and FIG. 5, step 150 is then performed to provide a FPC 70. Thereafter, step 160 is performed to press-bond one end 72 of the FPC 70 with the gold fingers 20 of the printed circuit board 10.

It can be known from the embodiments described above that the present invention may advantageously improve the thickness uniformity of the printed circuit board, thus avoiding the problem of failure in press-bonding the FPC with the printed circuit board caused by stress concentration.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A circuit board structure, comprising:
a printed circuit board;
a plurality of real circuits formed on a first area of one surface of the printed circuit board, wherein a first groove is formed between every two adjacent real circuits; and
a plurality of dummy circuits formed on a second area adjacent to the first area on the one surface of the printed circuit board, wherein a second groove is formed between every two adjacent dummy circuits, and the first lo groove and the second groove have substantially the same depths, and the dummy circuits and the real circuits have substantially the same thicknesses.

2. The circuit board structure as claimed in claim 1, further comprising:
a plurality of gold fingers formed on the other surface opposite to the one surface of the printed circuit board, wherein the gold fingers are substantially aligned with the first area and the second area, and the real circuits are electrically connected to the gold fingers, and the dummy circuits are electrically insulated from the gold fingers.

3. The circuit board structure as claimed in claim 2, further comprising:
a flexible printed circuit board (FPC), wherein one end of the FPC is press-bonded with the gold fingers.

4. The circuit board structure as claimed in claim 3, wherein the FPC is a chip on film (COF).

5. The circuit board structure as claimed in claim 1, wherein each of the dummy circuits is formed as a rectangle.

6. The circuit board structure as claimed in claim 5, wherein the rectangle has a width substantially ranged from 100 μm to 200 μm, and the rectangle has a length substantially ranged from 200 μm to 500 μm.

7. The circuit board structure as claimed in claim 1, wherein each of the lo dummy circuits is formed as a circle.

8. The circuit board structure as claimed in claim 7, wherein the circle has a diameter substantially ranged from 100 μm to 200 μm.

9. The circuit board structure as claimed in claim 1, wherein the dummy circuits are spaced from the real circuits at a distance that is substantially greater than 200 μm.

10. The circuit board structure as claimed in claim 1, wherein the ratio of the total area of the dummy circuits to the area of the second area is substantially ranged from 30% to 90%.

11. A liquid crystal display incorporating the circuit board structure as claimed in claim 1.

12. A manufacturing method of a circuit board structure, comprising:
providing a base board;
forming an electrically-conductive layer on one surface of the base board;
defining a first area and a second area adjacent to the first area on the electrically-conductive layer; and
simultaneously forming a plurality of first grooves and a plurality of second grooves on the first area and the second area, thereby respectively forming a plurality of real circuits on the first area, and a plurality of dummy circuits on the second area, wherein the first grooves and the second grooves have substantially the same depths, and the dummy circuits and the real circuits have substantially the same thicknesses.

13. The manufacturing method as claimed in claim 12, further comprising:
forming a plurality of gold fingers on the other surface opposite to the one surface of the base board, wherein the gold fingers are substantially aligned with the first area and the second area, and the real circuits are electrically connected to the gold fingers, and the dummy circuits are electrically insulated from the gold fingers.

14. The manufacturing method as claimed in claim 13, further comprising:
providing a flexible printed circuit board (FPC); and
press-bonding one end of the FPC with the gold fingers.

15. The manufacturing method as claimed in claim 14, wherein the FPC is a chip on film (COF).

16. The manufacturing method as claimed in claim 13, wherein each of the dummy circuits is formed as a rectangle.

17. The manufacturing method as claimed in claim 16, wherein the rectangle has a width substantially ranged from 100 μm to 200 μm, and the rectangle has a length substantially ranged from 200 μm to 500 μm.

18. The manufacturing method as claimed in claim 13, wherein each of the dummy circuits is formed as a circle.

19. The manufacturing method structure as claimed in claim 18, wherein the circle has a diameter substantially ranged from 100 μm to 200 μm.

20. The manufacturing method as claimed in claim 13, wherein the dummy circuits are spaced from the real circuits at a distance that is substantially greater than 200 μm.

21. The manufacturing method as claimed in claim 13, wherein the electrically-conductive layer is a copper material layer.

22. The manufacturing method as claimed in claim 13, wherein the ratio of the total area of the dummy circuits to the area of the second area is substantially ranged from 30% to 90%.
